(19) United States
(12) Patent Application Publication
(10) Pub. No.: US 2009/0298306 A1
(43) Pub. Date: Dec. 3, 2009

(54) Memory card connector

(76) Inventor: Pei-Chiao Hung, Tu-Cheng City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/153,830

(22) Filed: May 27, 2008

(51) Int. Cl. H05K 1/00

(52) U.S. Cl. 439/64

(57) ABSTRACT

A memory card connector is adapted for electrically connecting a memory card with a printed circuit board. The memory card connector includes an insulating housing having a base board, a plurality of signal terminals disposed in the base board to be soldered to the printed circuit board and contact the memory card, and a monitoring terminal disposed in the base board to be soldered to the printed circuit board. The monitoring terminal includes a monitoring portion and a connecting portion extending from the monitoring portion and tilting upward. A bottom of the monitoring portion defines at least two projections spaced from each other along the extending direction of the monitoring portion. Wherein the connecting portion is adapted for being pressed downward by the memory card to facilitate the projections to electrically contact the printed circuit board.

### BACKGROUND OF THE INVENTION

1. Field of the Invention

The present invention relates to a connector, and more particularly to a memory card connector.

2. The Related Art

With the development of electronic technology, memory cards are widely used in electronic products, such as digital cameras, personal digital assistants (PDA) and mobile phones etc. Traditionally, the electronic product defines a memory card connector configured therein so as to receive a memory card.

Traditionally, the memory card connector includes an insulating housing, a plurality of signal terminals and a monitoring terminal positioned in the insulating housing. The monitoring terminal defines a monitoring portion adapted for contacting a printed circuit board of the electronic product so as to monitor whether the memory card is fully inserted or not, when the memory card is inserted in the memory card connector. However, a bottom of the monitoring portion is flat-shaped, therefore, bad contact between the monitoring portion and the printed circuit board occurs sometimes due to the fact that the memory card has a thickness tolerance. As a result, the monitoring terminal is apt to lose monitoring efficacy.

### SUMMARY OF THE INVENTION

An object of the present invention is to provide a memory card connector adapted for electrically connecting a memory card with a printed circuit board. The memory card connector includes an insulating housing having a base board, a plurality of signal terminals disposed in the base board to be soldered to the printed circuit board and contact the memory card, and a monitoring terminal disposed in the base board to be soldered to the printed circuit board. The monitoring terminal includes a monitoring portion and a connecting portion extending from the monitoring portion and tilting upward. A bottom of the monitoring portion defines at least two projections spaced from each other along the extending direction of the monitoring portion. Wherein the connecting portion is adapted for being pressed downward by the memory card to facilitate the projections to electrically contact the printed circuit board.

As described above, the monitoring terminal defines the projections which ensures the monitoring terminal and the printed circuit board more sensitively contact each other so as to prevent the monitoring terminal from losing monitoring efficacy under the circumstance that the memory card has a thickness tolerance.

### BRIEF DESCRIPTION OF THE DRAWINGS

The present invention will be apparent to those skilled in the art by reading the following description of a preferred embodiment thereof, with reference to the attached drawings, in which:

FIG. 1 is a perspective view of a memory card connector of the present invention;

FIG. 2 is an exploded view of the memory card connector of FIG. 1;

FIG. 3 is a perspective view of a terminal assembly of the memory card connector;

FIG. 4 is a perspective view of a monitoring terminal of the memory card connector; and

FIG. 5 is a perspective view of an insulating housing and the terminal assembly of the memory card connector.

### DETAILED DESCRIPTION OF THE PREFERRED EMBODIMENT

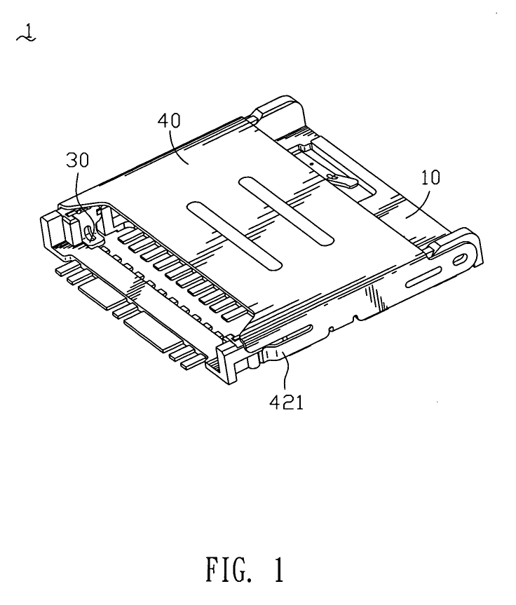

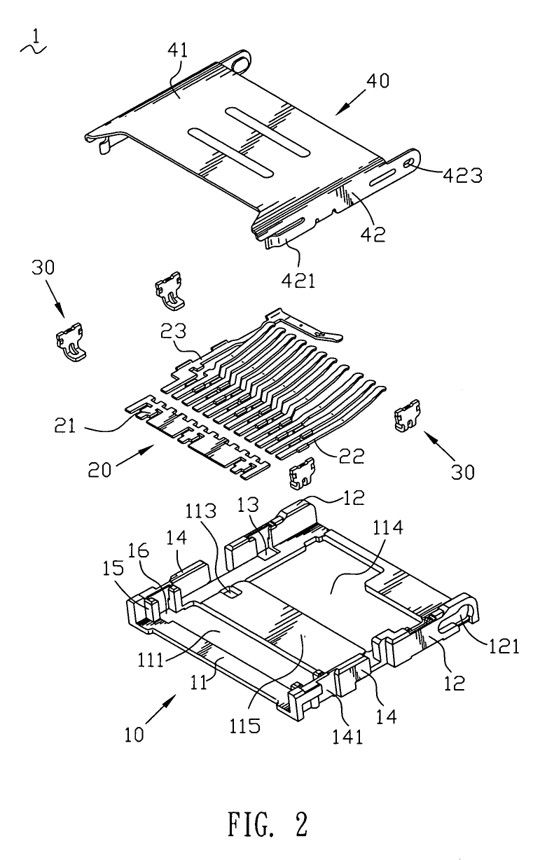

With reference to FIG. 1 and FIG. 2, a memory card connector 1 includes an insulating housing 10, a terminal assembly 20, a plurality of latches 30 and a cover 40.

Referring to FIG. 2, the insulating housing 10 has a rectangular base board 11. A front of the base board 11 defines a slot 111 extending transversely and penetrating from top to bottom. A rear of the base board 11 defines a receiving recess 114 paralleling with the slot 111 and penetrating from top to bottom. Accordingly, a bridge 115 is formed between the slot 111 and the receiving recess 114 and defines a cutting hole 113 in the left thereof. Two opposite sides of the base board 11 respectively extend upward to form a pair of first sidewalls 12 at the rear thereof and a pair of second sidewalls 14 at the front thereof. An outside of the first sidewall 12 concaves inward to form a receiving cavity 121 at rear and an inside of the first sidewall 12 defines a notch 13 penetrating the base board 11. An outside of the second sidewall 14 concaves inward to form a locking fillister 141 and an inside of the second sidewall 14 protrudes inward to form a pair of preventing blocks 15 vertically extending respectively. Accordingly, a channel 16 is formed between the two preventing blocks 15 and communicates with the slot 111. The cover 40 engages with the insulating housing 10 and has a base plate 41. Two opposite sides of the base plate 41 respectively extend downward and rearward to form a pair of side plates 42. A front of the side plate 42 defines a locking section 421 having a rear end connected with the side plate 42 and a front end freely bending inward. A rear of the side plate 42 protrudes inward to form a fixing bump 423.

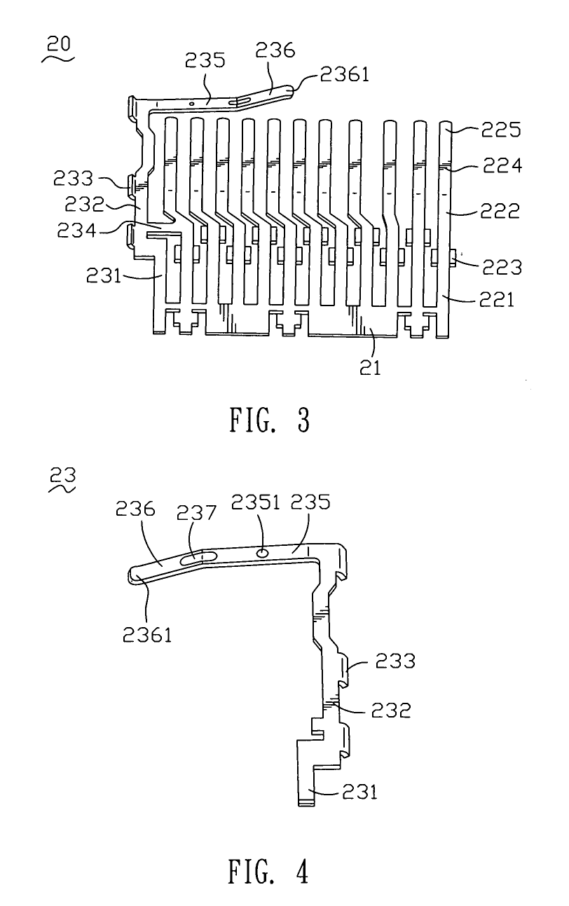

Referring to FIGS. 2-4, the terminal assembly 20 includes a shaping part 21, a plurality of signal terminals 22 and a monitoring terminal 23 respectively extending rearward from the shaping part 21 and arranged at regular intervals along a longwise direction of the shaping part 21. The signal terminal 22 has a first soldering section 221 extending rearward from the shaping part 21. The first soldering section 221 extends rearward to form a fixing section 222. Two fixing flanks 223 respectively protrude sideward from two opposite sides of the fixing section 222. A rear end of the fixing section 222 extends rearward and slightly inclines upward to form a connecting section 224. A rear end of the connecting section 224 defines a first contact section 225 slightly bending downward.

The monitoring terminal 23 is disposed in left of the signal terminals 22 and has a second soldering section 231 extending rearward from the shaping part 21. A rear of the second soldering section 231 bends leftward and then extends rearward to form a fixing arm 232 exceeding a rear of the first contact section 225 of the signal terminal 22. An outside of the fixing arm 232 defines a plurality of fixing portions 233 bending upward respectively. A connecting arm 234 extending transversely connects the fixing arm 232 and the adjacent fixing section 222. A rear end of the fixing arm 232 bends rightward and then transversely extends to form a monitoring portion 235. A bottom of the monitoring portion 235 protrudes downward to form a first projection 2351 at a middle thereof approximately. A free end of the monitoring portion 235 continues extending and inclines upward to form a connecting portion 236. An end of the connecting portion 236 defines a second contact section 2361 which is slightly flat-shaped. A second projection 237 protrudes downward across the junction of the monitoring portion 235 and the connecting portion 236.

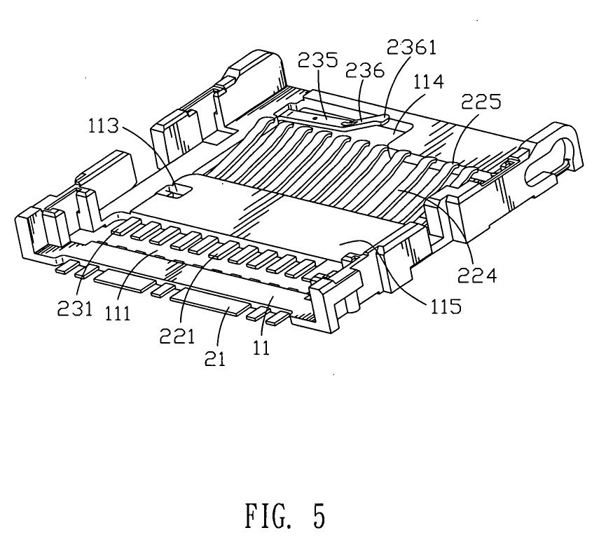

Referring to FIG. 5, the terminal assembly 20 is injection molded in the insulating housing 10. The shaping part 21 is fixed in the front of the base board 11 and stretches out of the front of the base board 11. The fixing sections 222 and the fixing flanks 223 of the signal terminals 22 are fixed in the bridge 115. The fixing arm 232 of the monitoring terminal 23 is fixed in the left of the base board 11 and the connecting arm 234 is partly located in the cutting hole 113. The first soldering sections 221 of the signal terminals 22 and the second soldering section 231 of the monitoring terminal 23 are located in the slot 111 of the base board 11. The connecting sections 224, the monitoring portion 235 and the connecting portion 236 are received in the receiving recess 114. The first contact sections 225 and the second contact section 2361 are positioned above the receiving recess 114. After the terminal assembly 20 is formed by injection molding in the insulating housing 10, the connecting arm 234 is cut off through the cutting hole 113 to enable the monitoring terminal 23 to separate from the adjacent signal terminal 22, the first soldering sections 221 and the second soldering section 231 are cut off at front to enable the monitoring terminal 23 and the signal terminals 22 separate from the shaping part 21.

Referring to FIG. 1, the latches 30 are respectively inserted in the notches 13 and the channels 16 of the insulating housing 10. The fixing bump 423 is pivotally received in the corresponding receiving cavity 121 of the insulating housing 10 to make the cover 40 openably and closably engage with the insulating housing 10. When the cover 40 is closed, the front end of the locking section 421 buckles into the corresponding locking fillister 141.

In use, the memory card connector 1 is located in an electronic product (not shown), the first soldering sections 221 and the second soldering section 231 are soldered to a printed circuit board (not shown) of the electronic product. The cover 40 is opened to allow a memory card (not shown) to be inserted into the memory card connector 1 and contact the first contact sections 225. The memory card presses the second contact section 2361 downward such that the first projection 2351 and the second projection 237 contact the printed circuit board so as to monitor whether the memory card is fully inserted or not. At last, the cover 40 is closed.

As described above, the monitoring terminal 23 defines the first projection 2351 and the second projection 237 which ensures that the monitoring terminal 23 and the printed circuit board more sensitively contact each other so as to prevent the monitoring terminal 23 from losing monitoring efficacy under the circumstance that the memory card has a thickness tolerance. Furthermore, the signal terminals 22 and the monitoring terminal 23 are formed by way of the shaping part 21 extending rearward, the monitoring terminal 23 and the adjacent signal terminal 22 are connected with the connecting arm 234. Therefore, the terminal assembly 20 can be integrally molded in a mold so as to reduce the cost.

What is claimed is:

1. A memory card connector adapted for electrically connecting a memory card with a printed circuit board, comprising:
an insulating housing having a base board;
a plurality of signal terminals disposed in the base board to be soldered to the printed circuit board and contact the memory card; and
a monitoring terminal disposed in the base board to be soldered to the printed circuit board, the monitoring terminal including a monitoring portion and a connecting portion extending from the monitoring portion and tilting upward, a bottom of the monitoring portion defining at least two projections spaced from each other along the extending direction of the monitoring portion, wherein the connecting portion is adapted for being pressed downward by the memory card to facilitate the projections to electrically contact the printed circuit board.

2. The memory card connector as claimed in claim 1, wherein the projection near the connecting portion is across the junction of the monitoring portion and the connecting portion.

3. The memory card connector as claimed in claim 1, wherein the projection near the connecting portion is rib-shaped.

4. The memory card connector as claimed in claim 1, wherein the monitoring terminal has a fixing arm fixed in the base board, the monitoring portion perpendicularly extends from one end of the fixing arm, a second soldering section extends from the other end of the fixing arm to be soldered to the printed circuit board.

5. The memory card connector as claimed in claim 4, wherein each of the signal terminals has a fixing section fixed in the base board, a first soldering section being soldered to the printed circuit board, and a first contact section positioned above a top of the base board for contacting the memory card.

6. The memory card connector as claimed in claim 5, wherein the base board defines a slot and a receiving recess apart from each other, the first soldering sections and the second soldering section are located in the slot, the monitoring portion and the connecting portion are received in the receiving recess, the first contact sections of the signal terminals are mounted above the receiving recess.

7. The memory card connector as claimed in claim 6, wherein the base board further defines a cutting hole between the slot and the receiving recess.

8. The memory card connector as claimed in claim 1, wherein the signal terminals and the monitoring terminal are integrally formed by way of extending from a shaping part fixed in the base board.
